(19) United States
(12) Patent Application Publication
(10) Pub. No.: US 2005/0074698 A1
(43) Pub. Date: Apr. 7, 2005

(54) Composite optical lithography method for patterning lines of significantly different widths

(75) Inventor: Yan Borodovsky, Portland, OR (US)

Correspondence Address: FISH & RICHARDSON, PC, 12390 EL CAMINO REAL, SAN DIEGO, CA, 92130-2081, US

(73) Assignee: Intel Corporation

(21) Appl. No.: 10/681,030

(22) Filed: Oct. 7, 2003

(51) Int. Cl. G03F 9/00; G03B 27/00; G03F 7/20

(52) U.S. Cl. 430/312; 430/5; 430/394; 430/396; 355/18; 355/77

(57) ABSTRACT

A composite patterning technique may include three lithography processes. A first lithography process forms a periodic pattern of alternating continuous lines of substantially equal width and spaces on a first photoresist. A second lithography process uses a non-interference lithography technique to break continuity of the patterned lines and form portions of desired integrated circuit features. The first photoresist may be developed. A second photoresist is formed over the first photoresist. A third lithography process uses a non-interference lithography technique to expose a pattern on the second photoresist and form remaining desired features of an integrated circuit pattern.

### BACKGROUND

An integrated circuit (IC) manufacturing process may deposit various material layers on a wafer and form a photosensitive resist (photoresist) on the deposited layers. The process may use lithography to transmit light through or reflect light from a patterned reticle (mask) to the photoresist. Light from the reticle transfers a patterned image onto the photoresist. The process may remove portions of the photoresist which are exposed to light. A process may etch portions of the wafer which are not protected by the remaining photoresist to form integrated circuit features.

The semiconductor industry may continually strive to reduce the size of transistor features to increase transistor density and to improve transistor performance. This desire has driven a reduction in the wavelength of light used in photolithographic techniques to define smaller IC features in a photoresist. Complex lithographic exposure tools may cost more to make and operate.

### BRIEF DESCRIPTION OF DRAWINGS

FIG. 1A illustrates an interference lithography apparatus.

FIG. 1B illustrates an example of a diffraction grating with slits which allow light to pass through and radiate a photoresist on a substrate.

FIG. 2 illustrates a latent or real image of an interference pattern of spaces and lines produced by the interference lithography apparatus of FIG. 1A or FIG. 1B.

FIG. 3A illustrates a desired final layout of lines with significantly different widths formed by first, second and third lithography processes.

FIG. 3B illustrates a layout after the latent pattern of continuous, non-exposed lines and exposed spaces of FIG. 2 has been altered by a second lithography process.

FIG. 3C shows an approximate exposed layout of the second lithography process mask or its corresponding database for maskless patterning.

FIG. 3D shows a corresponding layout of a second mask used by a third lithography process.

FIGS. 4A-4H illustrate an example of a second lithography process to expose areas on a photoresist and subsequent processes of developing, etching and stripping.

FIG. 5 illustrates a composite optical lithography exposure system with a movable wafer stage.

FIG. 6 shows an optical lithographic implementation of the second patterning system.

FIG. 7 is flow chart of a composite lithography patterning technique.

FIG. 8 shows a process for generating a layout of a mask for the second lithography process.

FIG. 9 shows an example of a design layout.

FIG. 10 shows an example of a remainder layout.

FIG. 11 shows a remainder layout after an expansion in a direction D.

### DETAILED DESCRIPTION

A conventional patterning technique may use expensive, diffraction-limited, high numerical aperture (NA), high aberration-corrected lens or tools equipped with complex illumination. A conventional patterning technique may also use complicated and expensive masks, which employ various phase shifters and complex optical proximity corrections (OPC).

The present application relates to a composite optical lithography patterning technique, which may form smaller integrated circuit features compared to conventional lithography techniques. The composite patterning technique may provide a higher density of integrated circuit features for a given area on a substrate.

The composite patterning technique may include two or more lithography processes. A first lithography process may use interference lithography to form a periodic alternating pattern of lines of substantially equal width and spaces on a first photoresist. A second lithography process may use a non-interference lithography technique to break continuity of the patterned lines formed by the first lithography process and remove resist over layout area where features of substantially larger width would need to be patterned. The first photoresist may be developed, and a second photoresist may be formed. A third lithography may expose features with significantly larger widths than the interference pattern line width.

The composite patterning technique may form patterns of lines with significantly different widths. For example, one line width may be 10% greater than another line width. As another example, one line width may be more than 30% greater than another line width. Patterned lines with significantly different widths may be desirable in integrated circuit (IC) manufacturing, for example, to pattern gates with significantly different widths. Gates with significantly different widths may optimize speed and/or power performance of an integrated circuit.

In another embodiment, the first process may include a non-interference lithography technique, and the second process may include an interference lithography technique.

First Lithography Process

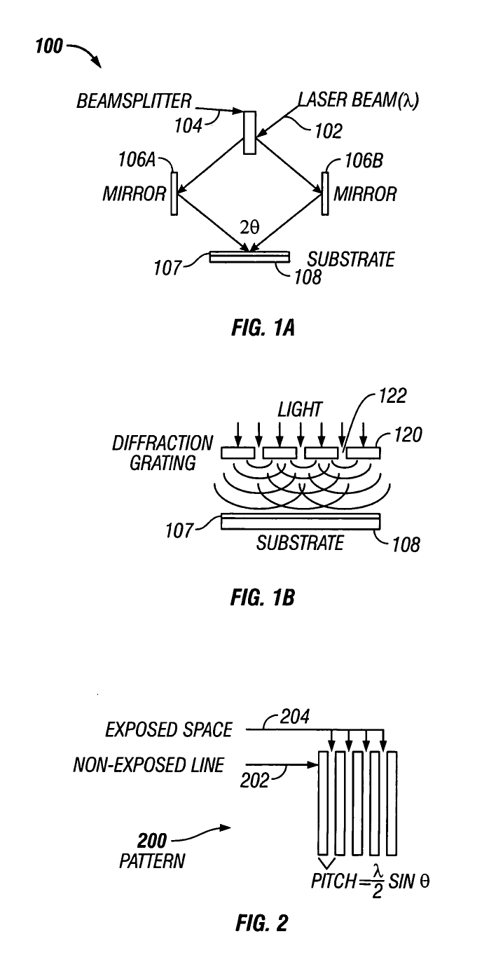

FIG. 1A illustrates an interference (interferometric) lithography apparatus 100. The interference lithography apparatus 100 may include a beam splitter 104 and two mirrors 106A, 106B. The beam splitter 104 may receive radiation, such as a conditioned (expanded and collimated) laser beam 102, from a radiation source with a pre-determined exposure wavelength (λ). The beam splitter 104 may direct the radiation 102 to the mirrors 106A, 106B. The mirrors 106A, 106B may form an interference pattern 200 (FIG. 2) on a substrate 108 with a photosensitive media, such as a photoresist layer 107. Many interferometric lithography tool designs with various complexity and sophistication are available. Either a positive or a negative photoresist may be used with the processes described herein. θ may be an angle between a surface normal of the photoresist 107 and a beam of radiation incident on the photoresist 107.

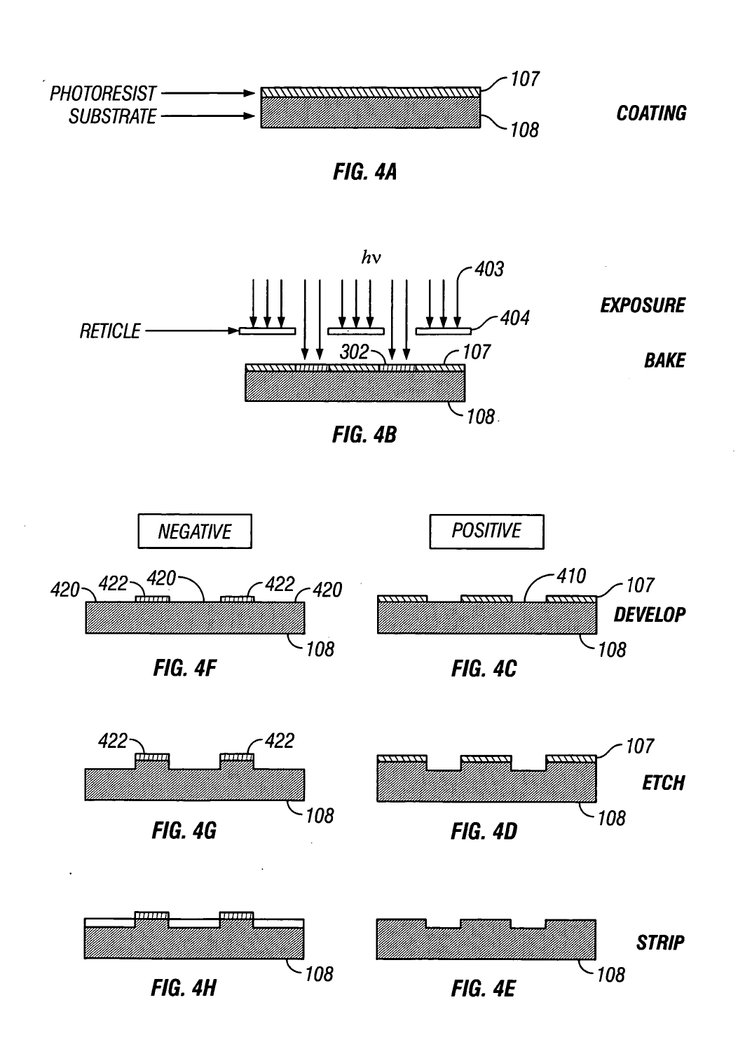

FIG. 2 illustrates a latent or real image of an interference pattern 200 of spaces 204 (exposed to light) and lines 202 (not exposed to light) produced by the interference lithography apparatus 100 of FIG. 1A. “Latent” refers to a pattern on the photoresist 107 which experienced a chemical reaction due to radiation but has not yet been developed in a solution to remove the exposed areas of the positive tone photoresist 107 (FIG. 4C described below). The lines 202 may have a substantially equal width. The spaces 204 may or may not have a width equal to the width of the lines 202.

“Pitch” is a sum of a line width and a space width in FIG. 2. As known to those of ordinary skill in optics, a “minimal pitch,” which can be resolved by a projection optical exposure apparatus with a pre-determined wavelength λ and numerical aperture NA, may be expressed as:
pitch/2=(k₁(λ/nᵢ))/NA,
where “NA” is the numerical aperture of a projection lens in the lithography tool, and “nᵢ” is the refractive index of a media between the substrate 108 and the last element of the optical projection system, e.g., mirrors 106A, 106B. Optical projection systems currently in use for microlithography use air, which has nᵢ=1. For liquid immersion microlithographic systems, nᵢ>1.4. For nᵢ=1, the pitch may be expressed as:
pitch/2=k₁λ/NA
pitch=2k₁λ/NA
where k₁ is known as Rayleigh's constant. “NA” may be expressed as:
   NA=n₀ sin θ.

NA may be equal to 1.

If k₁=0.25, and no is about equal to one, pitch may expressed as:
pitch=2(0.25)λ/n₀ sin θ≅λ/2 sin θ

Other values of k₁ may be greater than 0.25.

The interference lithography apparatus 100 of FIG. 1A may achieve a “minimal pitch” (a minimal line width plus space width) expressed as:
minimal pitch≅λ/2

The lines 202 and spaces 204 may have a pitch P₁ approaching λ₁/2, where λ₁ is the radiation wavelength used in the interference lithography process. The wavelength λ₁ may equal to 193 nm, 157 nm or an extreme ultraviolet (EUV) wavelength, such as 11-15 nm. Larger pitches may be obtained by changing the angle θ of interfering beams in FIG. 1A.

Minimal feature size of an exposed space 204 or non-exposed line 202 may be equal to, less than or larger than exposure wavelength divided by four (λ/4).

The first (interference lithography) process may define a width of all minimal critical features of a final pattern at a maximum density achievable by means of optical patterning with maximum process latitude.

Instead of the beam splitter 104, any light-splitting element may be used, such as a prism or diffraction grating, to produce a pattern 200 of alternating lines 202 and spaces 204 on the photoresist 107.

FIG. 1B illustrates an example of a diffraction grating 120 with slits 122 which allow light to pass through and radiate a photoresist 107 on a substrate 108. The diffraction grating 120 in conjunction with projection optics may produce the same interference pattern 200 (FIG. 2) as the beam splitter 104 and mirrors 106A, 106B of FIG. 1A.

The size of the interference pattern 200 formed by interference lithography may be equal to a die, multiple dies or a whole wafer, e.g., a 300-mm wafer or even larger future generation wafer sizes. Interference lithography may have excellent dimensional control of an interference pattern 200 due to a large depth of focus.

Interference lithography may have a lower resolution limit and better dimensional control than lens-based lithography. Interference lithography may have a higher process margin than lens-based lithography because depth of focus for interference lithography may be hundreds or thousands of microns, in contrast to a fraction of a micron (e.g., 0.3 micron) depth of focus for some conventional lithography techniques. Depth of focus may be important in lithography since a photoresist may not be completely flat since (a) the photoresist is formed over one or more metal layers and dielectric layers or (b) semiconductor wafer itself might not be sufficiently flat.

An embodiment of interference lithography may not need a complicated illuminator, expensive lenses, projection and illumination optics or a complex mask, in contrast to other lithography techniques.

Second Lithography Process

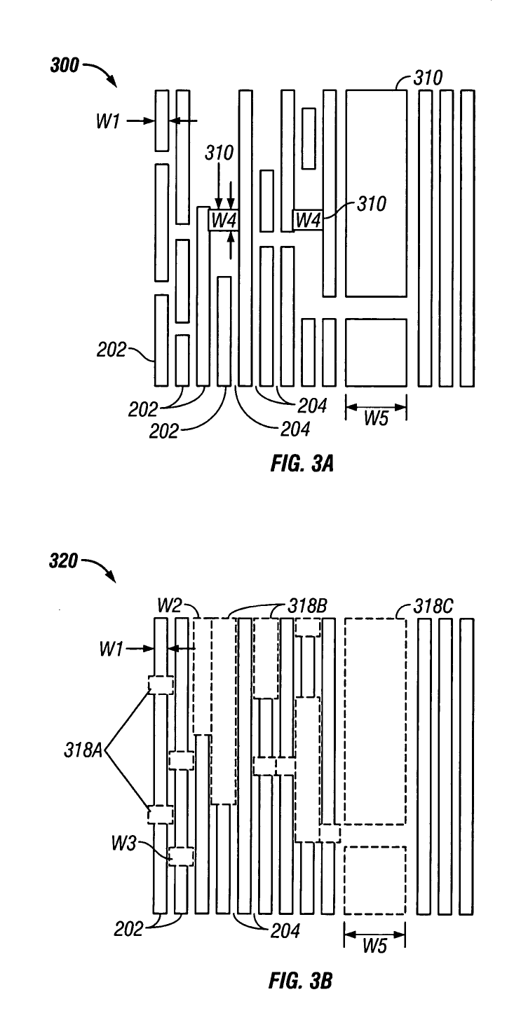

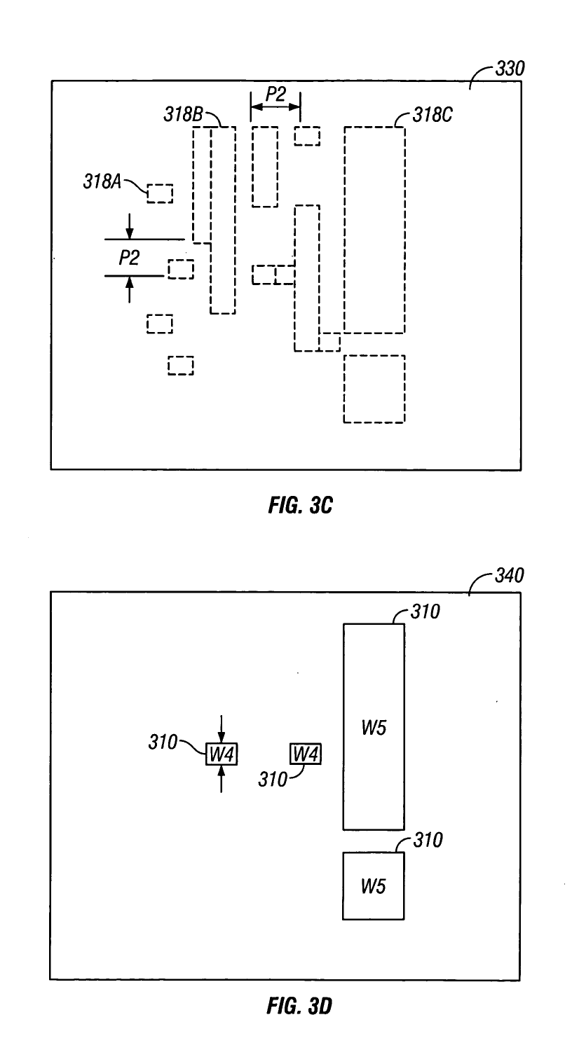

A second lithography process may include one or more non-interference lithography techniques, such as a conventional lithography technique, such as optical lithography, imprint lithography and electron-beam (e-beam) lithography. The second lithography process may use a mask (or reticle), as described below with reference to FIGS. 3C and 4B. The second lithography process may use a “trim” mask technique, another mask-based technique or a maskless patterning technique. The second lithography process may use extreme ultraviolet (EUV) lithography.

The second lithography process may remove unwanted portions of lines 202 with minimal line width W₁ of the pattern formed by the first lithography process.

FIG. 3A illustrates an example of a desired layout 300 of lines 202, 310 with significantly different widths W₁, W₄ and W₅ formed by the interference lithography process described above and second and third lithography processes described below. W4 is a line that connects two other lines 202 which are oriented orthogonally to W4. So “width” of W4 is orthogonal to width of those lines 202. The difference in layout and widths W₁, W₄, W₅ in FIG. 3A may be exaggerated for illustrative purposes.

FIG. 3B illustrates a layout 320 after the latent pattern 200 of continuous, non-exposed lines 202 and exposed spaces 204 of FIG. 2 (formed on the photoresist 107 by the interference lithography process) has been altered by a second lithography process. The second lithography process exposes areas 318A-318C, which expose (remove) portions of the non-exposed continuous lines 202 formed in a positive photoresist. The non-exposed lines 202 formed by the interference lithography process have a width W₁, which may be the width of a narrowest desired line 202 in FIG. 3A. Width W₁ is narrower than widths W₂, W₃ and W₅ of area 318A-318C (FIG. 3B) exposed to radiation by the second lithography process. The second lithography process may expose a large section 318C which exposes several lines 202 (FIG. 2) of the pattern 200.

The second lithography process breaks continuity and regularity of periodic alternating continuous lines 202 and space 204 produced in the first lithography process.

The pattern layout of the second lithography process' exposure mask 330 in FIG. 3C (or maskless patterning tool database) may be a Boolean difference between (a) a desired final pattern, such as the layout 300 in FIG. 3A, and (b) the pattern 200 (FIG. 2) formed by the interference lithography process. An approximate exposed layout of the second process' mask 330 (or its corresponding database for maskless patterning) is shown in FIG. 3C. FIG. 3C shows transparent regions 318A-318C in an opaque mask 330. The transparent regions 318A-318C expose radiation through the mask 330 if patterning of the second processing is produced by means of projection optical lithography for a positive resist. Thus, the spaces 204 and areas 318A-318C in FIG. 3B are exposed to radiation during the first and second lithography positive resist processes, respectively.

In an embodiment, the minimal pitch P₂ (FIG. 3C) of the second lithography process may be 1.5 times the size of the minimal pitch P₁ (λ₁/2) of the interference lithography process described above. Thus, P₂=1.5(P₁)=1.5(λ₁/2)=0.75λ₁.

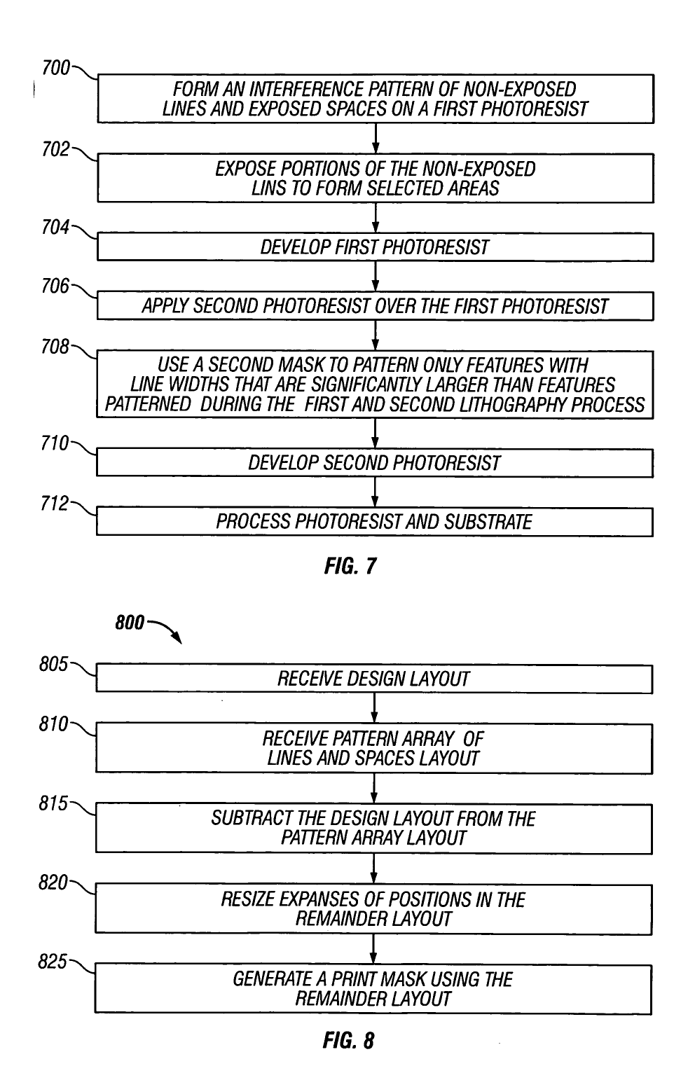

FIG. 7 is flow chart of a composite lithography patterning technique. At 700, an interference lithography process (described above), or a conventional lithography process employing an alternating phase shifted mask, forms the latent image pattern 200 (FIG. 2) of periodic continuous alternating lines 202 and spaces 204 on a first photoresist 107 with a minimal pitch approaching a resolution limit of optical imaging (k₁=0.25). A second lithography process exposes portions of the non-exposed lines 202 to form areas 318A-318C (FIG. 3B) at 702. After the second lithography exposure is complete, the first photoresist 107 may be developed at 704, as described below with reference to FIG. 4C.

A second photoresist may be applied over the first photoresist 107 (used by the first and second lithography processes) at 706. The second photoresist may be chemically different (distinct) from the first photoresist 107. The chemically different first and second photoresists may (a) prevent mixing of the photoresists and (b) enable chemically selective development of portions of the second photoresist exposed by a third lithography process without affecting the pattern formed in the first photoresist 107 by the first and second lithography processes.

Alternatively, the second photoresist may be the same chemically as the first photoresist but receive different processing.

Alternatively, a layer of λ₁ radiation absorbing organic or inorganic film may be deposited in between the first and second photoresists to prevent mixing of the first and second resists and prevent exposure of the first resist lines 202 to the third lithography process' radiation.

A third lithography exposure process at 708 may pattern features 310 (FIGS. 3A and 3D) with line widths W₄, W₅ that are significantly larger than features patterned during the first and second lithography processes. The third lithography exposure process may use a conventional lithography technique, as described above. The third lithography process may use a second mask (or database) and optics to form a pattern which has a larger pitch than the second lithography process pattern. The third lithography process may use the same apparatus as the second lithography process but with a different mask or database.

FIG. 3D shows a corresponding layout of a second mask used by the third lithography process. If a positive resist is used for the third lithography process, large features 310 in FIG. 3D with widths W₄ and W₅ of the second mask are oblique features on a transparent mask 340. Tonality of mask and features are reversed if a negative resist is used for the third lithography process.

A database for the second mask used in the third lithography process may contain only “large” lines W₄, W₅ (FIG. 3A) present in the original layout database which are sized to accommodate processing steps overlay requirements and mask making processing specificity known in the art of patterning.

The second photoresist may be developed at 710, which results in a final layout 300 (FIG. 3A) in the two photoresists. The substrate 108 and patterned photoresists are ready for subsequent processes in an IC process flow, such as etching (FIG. 4D), at 712.

FIGS. 4A-4H illustrate an example of a second lithography process to expose areas 320 (FIG. 3C) on the photoresist 107 and subsequent processes of developing, etching and stripping. A photoresist 107 may be formed (e.g., coated) on a substrate 108 in FIG. 4A. A latent or real interference pattern 200 (FIG. 2) may be formed on the photoresist 107 by the interference lithography apparatus 100 of FIG. 1A. A second lithography tool (second lithography process) may transmit light 403 through a patterned mask or reticle 404 to expose desired areas 302 of the photoresist 107 in FIG. 4B. The light 403 may start a reaction in the exposed areas 320. The light 403 may be ultraviolet, deep ultraviolet or extreme ultraviolet (EUV) radiation, for example, with a wavelength of about 11-15 nanometers (nm).

The photoresist 107 and substrate 108 may be removed from the lithography tool and baked in a temperature-controlled environment. Radiation exposure and baking may change the solubility of the exposed areas 320 and spaces 204 (FIG. 2) compared to unexposed areas of the photoresist 107.

The photoresist 107 may be “developed,” i.e., put in a developer and subjected to an aqueous (H₂O) based solution, to remove exposed areas 320 and spaces 204 of the photoresist 107 in FIG. 4C to form a desired pattern in the resist. If a “positive” photoresist is used, exposed areas 320 and spaces 204 may be removed by the solution. Portions 410 of the substrate 108 which are not protected by the remaining photoresist 107 may be etched in FIG. 4D to form desired circuit features. The remaining photoresist 107 may be stripped in FIG. 4E. If a “negative” photoresist is used, areas which are not exposed to radiation may be removed by the developing solution, as shown in FIG. 4F. Then portions 420 of the substrate 108 which are not protected by the remaining photoresist 422 may be etched in FIG. 4G to form desired circuit features. The remaining photoresist 422 may be stripped in FIG. 4H.

Combining an interference lithography technique and a non-interference lithography technique may provide high IC pattern density scaling (patterning at k₁=0.25 for any available wavelength).

Interference lithography, which patterns minimal pitch features, may extend 193-nm immersion lithography to 66-nm pitch and may extend an EUV interference tool capability down to 6.7-nm pitch.

Interference lithography may have an all-reflective design, e.g., Lloyds' mirror interferometric lithographic system, which may enable system design with available wavelengths between 157 nm and 13.4 nm, such as a neon discharge source (about 74-nm wavelength) and a helium discharge source (58.4-nm wavelength) with corresponding minimal pitches of 37 nm and 30 nm, respectively.

The second lithography process may be preceded by applying another layer of patterning media. The selected second lithography process may determine which patterning media is selected.

Alignment

An existing alignment sensor on the interference lithography apparatus 100 may align the pattern 200 (FIG. 2) produced by the first lithography process to a previous layer pattern formed by other processes. An existing alignment sensor may be above a wafer and be adapted to sense a mark on the wafer.

Alignment of the second and fourth lithography process to the first lithography process may be achieved by either indirect alignment (second lithography process patterning aligns to previous layer pattern by means of existing alignment sensors) or direct alignment (second lithography process patterning aligns to first lithography process pattern 200 directly) by means of a latent image alignment sensor.

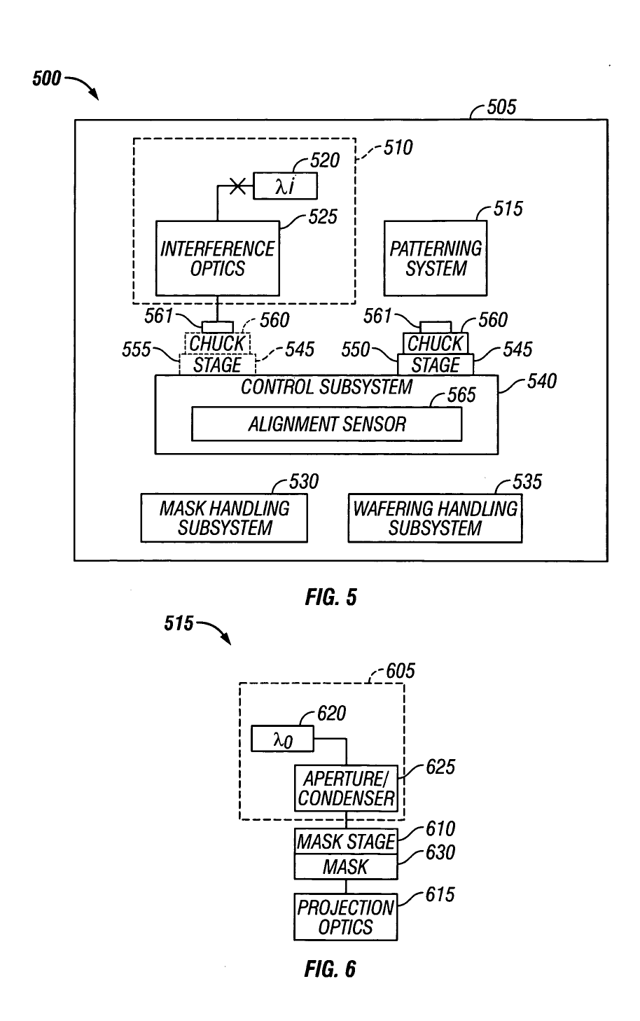

FIG. 5 illustrates a composite optical lithography system 500 with a movable wafer stage 545. The composite optical lithography system 500 may include an environmental enclosure 505, such as a clean room or other location suitable for printing features on substrates. The enclosure 505 encloses an interference lithography system 510 and a second (non-interference) patterning system 515. The interference lithography system 510 may include a collimated radiation source 520 and interference optics 525 to provide interferometric patterning on a photoresist.

The second patterning system 515 may use one of several techniques to pattern a photoresist. For example, the second patterning system 515 may be an e-beam projection system, an imprint printing system, or an optical lithography system. Alternatively, the second patterning system 515 may be a maskless module, such as an electron beam direct write module, an ion beam direct write module, or an optical direct write module.

The two systems 510, 515 may share a common mask handling subsystem 530, a common wafer handling subsystem 535, a common control subsystem 540, and a common stage 545. The mask handling subsystem 530 may position a mask in the system 500. The wafer handling subsystem 535 may position a wafer 561 in the system 500. The control subsystem 540 may regulate one or more properties or devices of system 500 over time. For example, the control subsystem 540 may regulate the position, alignment or operation of a device in system 500. The control subsystem 540 may also regulate a radiation dose, focus, temperature or other environmental qualities within environmental enclosure 505.

The control subsystem 540 can also translate the stage 545 between a first exposure stage position 555 and a second exposure stage position 550. The stage 545 includes a wafer chuck 560 for gripping a wafer 561. At the first position 555, the stage 545 and the chuck 560 may present a gripped wafer 561 to the interference lithography system 510 for interferometric patterning. At the second position 550, the stage 545 and the chuck 560 may present the gripped wafer 561 to the second patterning system 515 for patterning.

To ensure the proper positioning of a wafer 561 by the chuck 560 and the stage 545, the control subsystem 540 may include an alignment sensor 565. The alignment sensor 565 may transduce and control the position of the wafer 561 (e.g., using wafer alignment marks) to align a pattern formed by the second patterning system 515 with a pattern formed by the interference lithography system 510. Such positioning may be used when introducing irregularity into a repeating array of interferometric features, as discussed above.

FIG. 6 shows an optical lithographic implementation of the second patterning system 515. In particular, the second patterning system 515 may be a step-and-repeat projection system. Such a patterning system 515 may include an illuminator 605, a mask stage 610, a mask 630 and projection optics 615. The illuminator 605 may include a radiation source 620 and an aperture/condenser 625. The radiation source 620 may be the same as radiation source 520 in FIG. 5. Alternatively, the radiation source 620 may be a separate device. The radiation source 620 may emit radiation at the same or at a different wavelength as the radiation source 520.

The aperture/condenser 625 may include one or more devices for collecting, collimating, filtering, and focusing the emitted radiation from the radiation source 520 to increase the uniformity of illumination upon mask stage 610. The mask stage 610 may support a mask 630 in the illumination path. The projection optics 615 may reduce image size. The projection optics 615 may include a filtering projection lens. As the stage 545 translates a gripped wafer 561 for exposure by the illuminator 605 through mask stage 610 and projection optics 615, the alignment sensor 565 may ensure that the exposures are aligned with a repeating array 200 of interferometric features to introduce irregularity into the repeating array 200.

FIG. 8 shows a process 800 for generating a layout of a mask for the second lithography process described above. The process 800 may be performed by one or more actors (such as a device manufacturer, a mask manufacturer, or a foundry) acting alone or in concert. The process 800 may also be performed in whole or in part by a data processing device executing a set of machine-readable instructions.

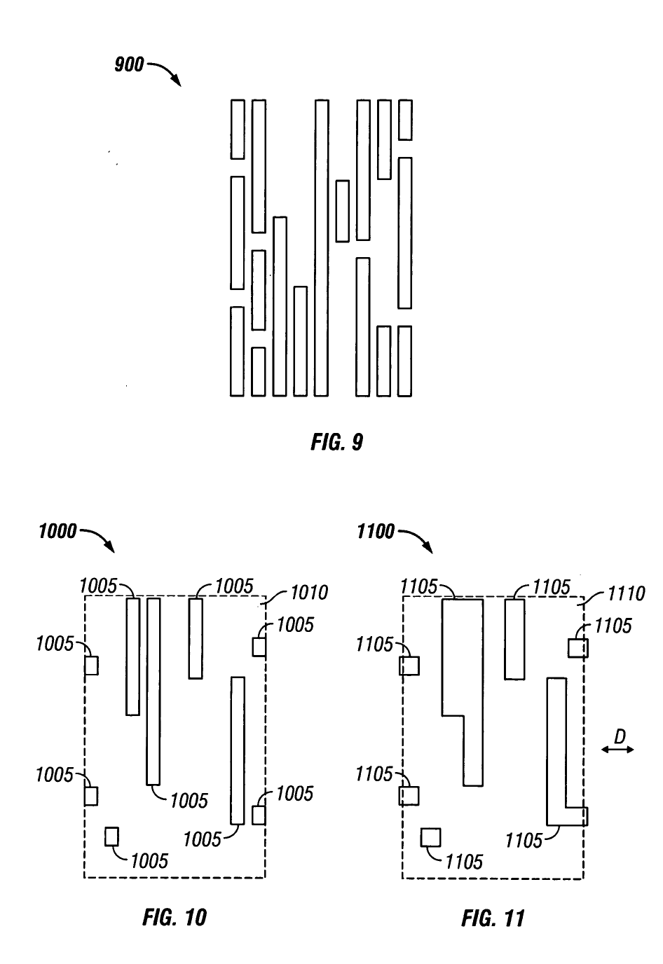

The actor performing the process 800 receives a design layout at 805. The design layout is an intended physical design of a layout piece or substrate after processing. FIGS. 3A and 9 show examples of such design layouts 300, 900. The design layout 300, 900 may be received in a machine-readable form. The physical design of the layout 300, 900 may include a collection of trenches and lands between the trenches. The trenches and lands may be linear and parallel. The trenches and lands need not repeat regularly across the entire layout piece. For example, the continuity of one or both of trenches and lands may be cut at arbitrary positions in the layout 300, 900.

Returning to FIG. 8, the actor performing the process 800 may also receive a pattern array layout 200 of alternating, parallel lines 202 and spaces 204 (FIG. 2) at 810. The pattern array layout 200 may be formed on a photoresist 107 by interferometric lithography techniques, i.e., interference of radiation. The pattern array layout 200 may be received in a machine-readable form.

Returning to FIG. 8, the actor may subtract the design layout 900 (FIG. 9) from the pattern array layout 200 (FIG. 2) at 815. The subtraction of the design layout 900 from the pattern array layout 200 may include aligning trenches 332 in the design layout 900 with either lines or spaces in the pattern array layout 200 and determining positions where irregularity in the design layout 900 prevents complete overlap with the pattern array layout 200.

FIGS. 3C and 10 show examples of remainder layouts 330, 1000 that indicate positions where the design layouts 300, 900 do not completely overlap with the pattern array layout 200 (FIG. 2). The remainders layouts 330, 1000 may be in machine-readable form. The subtraction may be Boolean because positions in the remainder layouts 330, 1000 may have only one of two possible states. In particular, the remainder layout 1000 includes expanses of first positions 1005 with a “not overlapped” state and a contiguous expanse of second positions 1010 with an “overlapped” state.

Returning to FIG. 8, the actor may resize expanses of positions in the remainder layout 1000 at 820. The resizing of the remainder layout 1000 may result in a changed machine-readable remainder layout 1100 in FIG. 11. FIG. 11 shows a remainder layout 1100 after such an expansion in a direction D. When the pattern array is an array 200 of parallel lines 202 and spaces 204, the size of expanses 1105 with a present state may be increased in the direction perpendicular to the lines 202 and spaces 204. Some expanses 1105 may merge.

Returning to FIG. 8, the actor may generate a print mask using the remainder layout 1000 in FIG. 10 at 825. The print mask may be generated using the resized remainder layout 1100 of FIG. 11 to create arbitrarily shaped features for introducing irregularity into a repeating array, such as the pattern array 200 (FIG. 2). The generation of the print mask may include generating a machine-readable description of the print mask. The generation of the print mask may also include tangibly embodying the print mask in a mask substrate.

Alternatively, if the second lithography process uses EUV wavelengths, elements of an EUV lithography system, including the mask to be used, may be reflective. The clear (transmissive) areas on a non-EUV mask will be reflective areas on a EUV mask, and opaque (chrome) areas on a non-EUV mask will be absorptive areas on an EUV mask.

A number of embodiments have been described. Nevertheless, it will be understood that various modifications may be made without departing from the spirit and scope of the application. Accordingly, other embodiments are within the scope of the following claims.

1. A system comprising:
a first apparatus to radiate a periodic pattern of alternating non-exposed lines and exposed spaces on a first photoresist, the lines having a substantially equal first width; and
a second apparatus to expose a portion of at least one line to radiation to form a feature with a second width, the second width being larger than the first width of the lines, the second apparatus to radiate an area of a second photoresist over the first photoresist, the area having a third width.

2. The system of claim 2, wherein a pitch of a pattern produced by the second apparatus is greater than or equal to one and a half times a minimal pitch of the periodic pattern of alternating lines and spaces.

3. The system of claim 1, wherein the second photoresist is chemically distinct from the first photoresist.

4. The system of claim 1, wherein the first apparatus comprises a beamsplitter.

5. The system of claim 1, wherein the first apparatus comprises a diffraction grating.

6. The system of claim 1, wherein the first apparatus comprises a optical projection lithography tool using an alternating phase shifter mask.

7. The system of claim 1, wherein the second apparatus comprises a mask-based optical lithography tool.

8. The system of claim 1, wherein the second apparatus comprises a maskless optical lithography tool with a database.

9. The system of claim 1, wherein the second apparatus comprises an imprint lithography tool.

10. The system of claim 1, wherein the second apparatus comprises an imprint electron beam tool.

11. A method comprising:
radiating a periodic pattern of alternating non-exposed lines and exposed spaces on a first photoresist, the lines having a first width; exposing a portion of at least one line to radiation to break continuity of the line and regularity of pattern and form a feature with a second width, the second width being greater than the first width;
developing the first photoresist;
forming a second photoresist over the first photoresist; and
radiating an area of the second photoresist, the area having a third width.

12. The method of claim 11, wherein a pitch of the feature is greater than or equal to one and a half times a pitch of the interference pattern.

13. The method of claim 11, wherein the radiation has a wavelength, the alternating pattern of lines and spaces having a pitch equal to about the wavelength divided by two.

14. The method of claim 11, wherein the second photoresist is chemically distinct from the first photoresist.

15. The method of claim 11, wherein the second photoresist is separated from first photoresist by means of third barrier layer residing between the first and second photoresists, the barrier layer having a property of sufficiently high absorption of light to expose the first photoresist and a chemical structure that prevents mixing of the first and second photoresists.

16. The method of claim 11, further comprising aligning the feature to the interference pattern.

17. The method of claim 11, further comprising aligning the area to the feature.

18. The method of claim 11, further comprising generating a print mask from subtraction of (a) a final design layout for a given layer from (b) the interference pattern.

19. An apparatus comprising:
a first patterning apparatus including an interference exposure module to produce a first exposure of spaces and lines on a photoresist;
a second patterning apparatus to produce a second exposure, the second exposure reducing regularity of the first exposure; and
a third patterning apparatus to produce a third exposure on a second photoresist over the first photoresist, the third exposure exposing areas wider than features of the second exposure.

20. The apparatus of claim 19, further comprising an alignment sensor to align the second exposure to the first exposure formed.

21. The apparatus of claim 19, further comprising a common control system to move the first photoresist in a first position for the interference exposure module and in a second position for the second patterning module.

22. The apparatus of claim 19, where the interference exposure module comprises an interference lithography module, and the second patterning module comprises a projection optical lithography system, the projection optical lithography system comprising projection optics, a wafer stage, and a mask to reduce regularity in the first exposure created by the interference exposure module.

23. The apparatus of claim 19, where the interference exposure module comprises an interference lithography module, and the second patterning module comprises an imprint system that comprises projection optics, a wafer stage, and a mask to reduce regularity in the first exposure created by the interference exposure module.

24. The apparatus of claim 19, where the interference exposure module comprises an interference lithography module, and the second patterning module comprises an electron projection system that comprises projection optics, a wafer stage, and a mask to reduce regularity in the first exposure created by the interference exposure module.

25. The apparatus of claim 19, where the interference exposure module comprises an interference lithography module, and the second patterning module comprises a maskless module to reduce regularity in the first exposure created by the interference exposure module, projection optics and a wafer stage.

26. The apparatus of claim 25, wherein the maskless module comprises an optical direct write module.

27. The apparatus of claim 25, wherein the maskless module comprises an electron beam direct write module.

28. The apparatus of claim 25, wherein the maskless module comprises an ion beam direct write module.

29. The apparatus of claim 19, where the interference exposure module comprises an interference lithography module, and the second patterning module comprises an X-ray proximity projection system that contains a mask to reduce regularity in a pattern created by the interference exposure module, projection optics and a wafer stage.

30. A method comprising:
receiving a pre-determined design layout;
receiving a pattern layout of alternating, parallel lines and spaces; and
subtracting the design layout from the pattern layout of alternating, parallel lines and spaces to form a remainder layout.

31. The method of claim 30, further comprising aligning features of the design layout with at least one of the lines and spaces of the pattern layout.

32. The method of claim 30, further comprising generating a machine-readable description of a print mask with the remainder layout.

33. The method of claim 30, further comprising generating a print mask with the remainder layout.

34. The method of claim 30, further comprising resizing features of the remainder layout.
